(19) United States
(12) Patent Application Publication
(10) Pub. No.: US 2020/0072871 A1
(43) Pub. Date: Mar. 5, 2020

(54) ULTRA LOW-COST, LOW LEADTIME, AND HIGH DENSITY SPACE TRANSFORMER FOR FINE PITCH APPLICATIONS

(71) Applicant: Intel Corporation, Santa Clara, CA (US)

(72) Inventors: Pooya Tadayon, Portland, OR (US); Joe F. Walczyk, Tigard, OR (US); Keith J. Marting, Hillsboro, OR (US)

(73) Assignee: Intel Corporation, Santa Clara, CA (US)

(21) Appl. No.: 16/490,517

(22) PCT Filed: Mar. 31, 2017
(86) PCT No.: PCT/US2017/025515

§ 371 Date: Aug. 30, 2019

(51) Int. Cl. G01R 1/073; H05K 1/11; H05K 3/42; H05K 3/00; H05K 3/40

(52) U.S. Cl. CPC G01R 1/07378; H05K 1/113; H05K 3/42; H05K 2201/10234; H05K 3/4015; H05K 2201/09609; H05K 2201/09636; H05K 3/0047

(57) ABSTRACT

Space transformation technology for probe cards at sort is disclosed. In one example, a space transformer transforms a pitch of electrical contacts from a first distribution to a second distribution. The space transformer comprises a substrate with opposite first and second sides; and vias extending through the substrate between the first and second sides and oriented at different angles with respect to one another. In one example, a tester system or probe card for a die comprises a printed circuit board (PCB) with pads having a pad pitch; and a space transformer operatively coupled to the PCB, and having vias extending from the pads of the PCB through the space transformer at different angles with respect to one another and configured to electrically connect to contacts on the die having a contact pitch different than the pad pitch.

### TECHNICAL FIELD

Embodiments described herein relate generally to space transformation, and more particularly to a space transformer with fanned-out vias to scale pitch from a fine pitch on silicon to a loose pitch of a printed circuit board (PCB).

### BACKGROUND

Space transformation is a key component for probe cards at sort. The silicon bump pitch is often an order of magnitude smaller than the pitch capability of a printed circuit board (PCB) that mates with the test equipment. As a result, a space transformer is needed to translate the fine pitch on the silicon to a looser pitch that is compatible with the PCB. Existing space transformation technologies—primarily ceramic and organic based—are challenged by ongoing silicon pitch scaling. A key issue with these technologies is the ability to route out all the input/outputs (IOs) to a looser pitch as the pitch scales. As three-dimensional (3D) products begin to push the envelope below 50 um (micrometer) pitch, these technologies become less appealing. Silicon space transformer technology has the capability to scale, but comes with its own set of challenges. Silicon space transformers are generally very expensive and have long lead times. Such silicon space transformers, can scale well below 50 um pitch, but are extremely expensive because they require similar manufacturing processes as active silicon and utilize expensive masks and toolsets.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1a schematically shows a cross-sectional side view of a space transformer operatively coupled between a printed circuit board (PCB) and an electrical device or die in accordance with one example;

FIG. 1b schematically shows an exploded cross-sectional side view of the space transformer, PCB and electrical device or die of FIG. 1a;

FIG. 2 schematically shows a cross-sectional side view of the space transformer of FIG. 1a;

FIG. 3 schematically shows a cross-sectional side view of a space transformer in accordance with one example;

FIG. 4 schematically shows a cross-sectional side view of a space transformer in accordance with one example;

FIG. 5 schematically shows a partial cross-sectional side view of a space transformer in accordance with one example;

FIG. 6 schematically shows a partial cross-sectional side view of a space transformer in accordance with one example;

FIG. 7 schematically shows a top view of a space transformer in accordance with one example;

FIG. 9 illustrates a method in accordance with one example;

FIGS. 10a-c illustrate a method in accordance with one example;

FIGS. 11a-d illustrate a method in accordance with one example;

FIG. 12 is a series of pictures of an x-ray cross-section in accordance with one example; and

FIG. 13 is a picture in accordance with one example.

Reference will now be made to the exemplary embodiments illustrated, and specific language will be used herein to describe the same. It will nevertheless be understood that no limitation of the scope or to specific invention embodiments is thereby intended.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this specification and the appended claims, the singular forms “a,” “an” and “the” include plural referents unless the context clearly dictates otherwise. Thus, for example, reference to “a layer” includes a plurality of such layers.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the specification, like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. It is understood that express support is intended for exact numerical values in this specification, even when the term “about” is used in connection therewith.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### Example Embodiments

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

In one example, a space transformer transforms a pitch of electrical contacts from a first distribution to a second distribution. The space transformer comprises a substrate with opposite first and second sides; and vias extending through the substrate between the first and second sides and oriented at different angles with respect to one another. In one example, a tester system or probe card for a die comprises a printed circuit board (PCB) with pads having a pad pitch; and a space transformer operatively coupled to the PCB, and having vias extending from the pads of the PCB through the space transformer at different angles with respect to one another and configured to electrically connect to contacts on the die having a contact pitch different than the pad pitch.

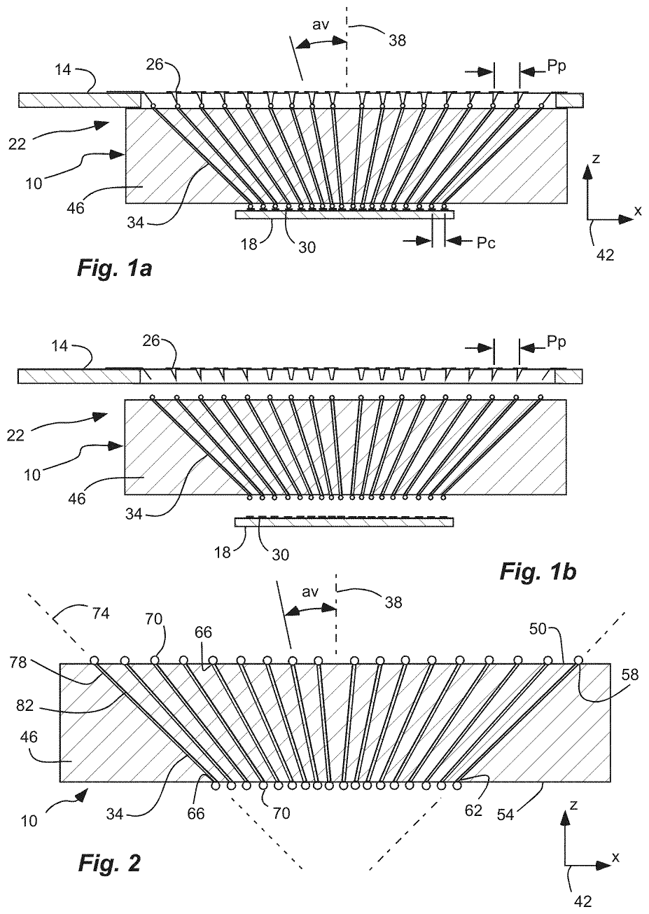

FIG. 1A shows a schematic cross-sectional side view of a space transformer 10 operatively coupled between a printed circuit board (PCB) 14 and an electrical device or die 18 in accordance with one example. FIG. 1b shows a schematic exploded cross-sectional side view of the space transformer 10, PCB 14 and electrical device or die 18. The space transformer 10 and the PCB 14 can form at least part of a tester system or probe card 22 for dies 18 on a wafer. The die(s) 18 in FIGS. 1a and 1b can represent a single die or multiple dies on a wafer. The PCB 14 can have electrical connections or pads 26. The pads 26 can have a pad pitch Pp (or a first distribution). The pad pitch can be compatible with a printed circuit board (PCB) that can mate with test equipment during sort processing of the dies 18. The pad pitch can be characterized as a looser, wider and/or greater pitch (with respect to a contact pitch of the die 18, as discussed later). The die(s) 18 can have contacts 30 on the die that have a contact pitch Pc (or a second distribution). The contact pitch can be characterized as tight, fine, narrower and/or lesser pitch (with respect to the pad pitch). The contact pitch of the die 18 and contacts 30 can be different than the pad pitch of the PCB 14 and pads 26.

The space transformer 10 can be operatively coupled to the PCB 14. The space transformer 10 can be connected to the PCB 14 through a permanent or temporary electrical connection. In one aspect, the space transformer 10 can be carried by the PCB 14. In another aspect, the space transformer 10 can be disposed between the PCB 14 and the die(s) 18. The space transformer 10 has vias 34 therein and extending through the space transformer. The vias 34 extend between the pads 26 of the PCB 14, through the space transformer 10, to the contacts 30 of the die(s) 18. In one aspect, the vias 34 extend from the pads 26 of the PCB 14 through the space transformer 10, to electrically connect to the contacts 30 of the die(s) 18. In one aspect, the space transformer 10 can transform a pitch of electrical contacts from a first distribution to a second distribution. In one aspect, the pads 26 of the PCB 14 can be or can define the first distribution of electrical contacts, while the contacts 30 of the die(s) 18 can be or can define the second distribution. A pitch of the ends of the vias 34 on opposite sides of the space transformer 10 (or the substrate 46) can be different.

The vias 34 extend through the space transformer 10 and are oriented at different angles with respect to one another. Thus, the vias 34 can define multi-angle vias. In one aspect, the vias 34 can be oriented at different angles av with respect to a longitudinal axis 38. The longitudinal axis can be orthogonal to or perpendicular to the PCB 14, the space transformer 10, and/or the die(s) 18. The vias 34 can be angled or inclined, such as at an acute angle, with respect to the longitudinal axis 38 or the space transformer 10. In another aspect, the vias 34 can be oriented at different angles with respect to an x-y-x reference frame 42. While one via may have the same angle with respect to another via, or even with respect to the longitudinal axis 38, in one aspect, at least one via and/or group of vias is oriented at a different angle with respect to another via and/or group of vias, and/or with respect to the x-y-x reference frame 42 and/or with respect to the longitudinal axis 38. Thus, while two or more vias may have the same angle av with respect to the longitudinal axis 38, in one aspect, at least one via and/or group of vias is oriented and/or positioned differently about the longitudinal axis 38 with respect to another via and/or group of vias.

The vias 34 oriented at different angles achieves a space transformation; scaling the pitch between the pad pitch Pp of the pads 26 of the PCB 14 and the contact pitch Pc of the contacts 30 of the die(s) 18, thus transforming a pitch of electrical contacts from a first distribution to a second distribution. In one aspect, the vias 34 fan out from a tight and/or fine pitch (such as the contact pitch Pc of the contacts 30 of the die 18) to a loose pitch (such as the pad pitch Pp of the pads 26 of the PCB 14). In one aspect, the vias 34 can transform a pitch of the second distribution of electrical contacts, such as the contact pitch Pc of the contacts 30 of the die(s) 18, to less than three-quarters of a pitch of the first distribution of electrical contacts, such as the pad pitch Pp of the pads 26 of the PCB 14. In another aspect, the vias 34 can transform a pitch of the second distribution of electrical contacts, such as the contact pitch Pc of the contacts 30 of the die(s) 18, to less than half of a pitch of the first distribution of electrical contacts, such as the pad pitch Pp of the pads 26 of the PCB 14. In another aspect, the vias 34 can transform a pitch of the second distribution or electrical contacts, such as the contact pitch Pc of the contacts 30 of the die(s) 18, to less than a quarter of a pitch of the first distribution of electrical contacts, such as the pad pitch Pp of the pads 26 of the PCB 14.

FIG. 2 shows a schematic cross-sectional side view of only the space transformer 10. The space transformer 10 has a substrate 46 with opposite first and second sides 50 and 54, respectively. In addition, the space transformer 10 has probes 56 extending from the vias 34 on the second side 54 of the substrate 46. The probes 56 make an electrical connection with the contacts 30 on the die(s) 18, as shown in FIG. 1a. The probes 56 can have a probe pitch that is the same as the contact pitch of the contacts 30 on the die(s) 18 described above. The vias 34 extend through the substrate 46 between the first and second sides 50 and 54. Each end of the vias can form or define electrical contacts 58 and 62 on the first and second sides 50 and 54 of the substrate 46, respectively. In one aspect, a bond pad 66 can be disposed at an end of each via 34. In another aspect, a solder ball 70 can be disposed at an end of each via 34. In another aspect, both a bond pad 66 and a solder ball 70 can be disposed at an end of each via 34. In another aspect, a wire 72 can be disposed at an end of each via 34 on the second side 54 of the substrate 46. The probes 56 can be solder balls 70, wires 72 or any suitable material or structure that can engage the contacts 30 on the die(s) 18, such as a wavy wire, an angled straight wire acting as a cantilever, a torsion bar, a coiled micro-spring, etc. The electrical contacts 62 or probes 56 on the second side 54 of the substrate 46 can have a narrower pitch than the electrical contacts 58 on the first side of the substrate 46. The vias 34 form an array or grid of contacts 58 and 62 on each side 50 and 54 of the substrate 46. In one aspect, the vias 34 collectively form a conical projection 74 through the substrate 46. The vias 34 can transform a pitch of ends (bond pads 66 and/or solder balls 70) of the vias on opposite sides 50 and 54 of the substrate 46 by less than three-quarters in one aspect, by less than half in another aspect, and by less than a quarter in another aspect.

The substrate 46 can have a size and shape (in x, y directions) to fit and/or mate with the PCB 14. In addition, the substrate has a thickness (in the z direction). (In FIGS. 1a, 1b and 2, they direction is into the page.) In one aspect, the substrate 46 can have a thickness between about 250-500 um (micrometers). In one aspect, the substrate 46 can be formed of a material with a low coefficient of thermal expansion (CTE), and high modulus, and that is suitable for laser machining. For example, the material of the substrate 46 can be or can comprise alumina, aluminum nitride, silicon nitride, etc. In one aspect, the substrate 46 can be a homogeneous material. A homogeneous material can allow for thinner substrates. For example, the substrate can be a homogeneous material that is about 250-500 um thick. In another aspect, the material of the substrate 46 can be or can comprise a heterogeneous material. A heterogeneous material can allow for a thicker substrate that can still be laser micro-machined. The longitudinal axis 38 can be orthogonal or perpendicular to the substrate 46, and/or first side 50 thereof. The vias 34 can be angled or inclined, such as at an acute angle, with respect to the longitudinal axis 38 and/or the substrate 46.

In one aspect, the vias 34 can be linear. Linear vias 34 can be easier to form. The linear vias 34 extending through the substrate 46 at an angle or incline with respect to the substrate 46 and/or longitudinal axis 38 allow for space transformation without the need for all vertical vias and lateral escape routing (staircase like) of input/outputs (IOs) with silicon space transformers. When many IOs are involved, the lateral routing becomes more challenging as there is not enough space to escape. In addition, lateral routing can take months to design and manufacture. The simpler linear and angled/inclined vias 34 can be designed in less than a day and fabricated in less than one to two weeks.

The substrate 46 can have holes 78 extending through the substrate 46 between the first and second sides 50 and 54. The holes 66 can be drilled in the substrate 46 with a laser, as discussed in greater detail below. The holes 78 can have different angles with respect to one another, as discussed above with respect to the vias 34. An electrically conductive material 82 is disposed in the holes 78, and extends between the first and second sides 50 and 54, and defines the vias 34 through the substrate 46. The electrically conductive material 82 can comprise a conductive paste (thermally cycled to evaporate flux and solidify the material), plating, wires, or chemical vapor deposition (CVD) as discussed in greater detail below.

As described above, in one aspect the vias 34 can be linear. In another aspect, the vias can be non-linear.

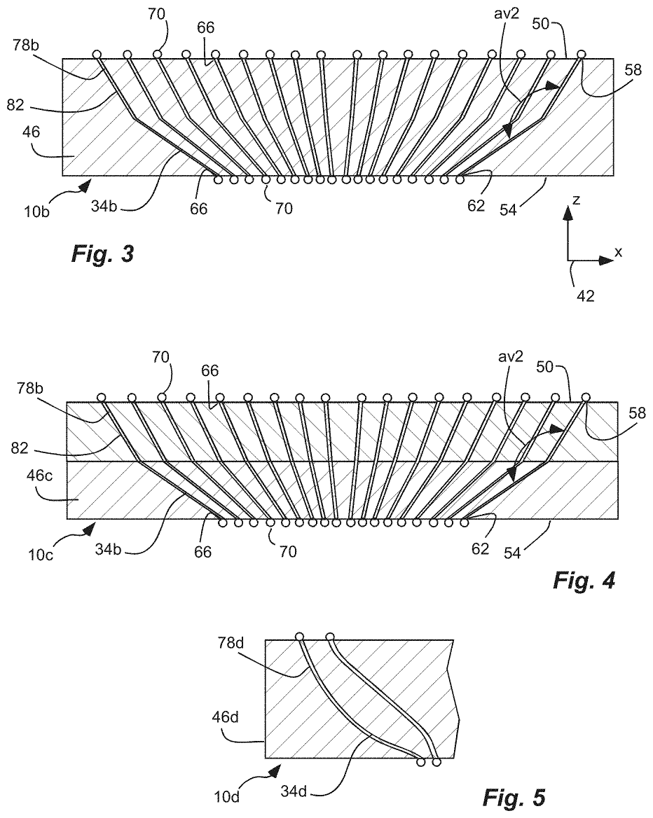

FIG. 3 is a schematic cross-sectional side view of a space transformer 10b in accordance with one example. The vias 34b can be multi-angled with multiple angles in each via at an obtuse angle av2 with respect to one another. Each via 34b can have multiple segments forming the multiple angles. Each segment of the each via 34b can be formed by drilling holes 78b at different angles from opposite sides of the substrate 46 which join together.

As described above, in one aspect the substrate can be homogeneous. In another aspect, the substrate can be heterogeneous.

FIG. 4 is a schematic cross-sectional side view of a space transformer 10c in accordance with one example. The substrate 46c can comprise multiple portions or substrates joined together. In addition, the vias 34b can be multi-angled with multiple angles in each via at an obtuse angle av2 with respect to one another. Each via 34b can have multiple segments disposed in a different one of the multiple portions or substrates of the substrate 46c forming the multiple angles. Each segment of the each via 34b can be formed by drilling holes 78b at different angles in different portions or substrates of the substrate 46c which join together when the portions or substrates are joined together.

FIG. 5 is a schematic cross-sectional side view of a space transformer 10d in accordance with one example. The vias 34d can be arcuate. In one aspect, the vias 34d can form an arc. The arc can have a single segment with a single radius of curvature or center, or can have multiple segments with different radii or centers. Similarly, the holes 78d can be arcuate. The arcuate holes 78d can be formed by 3D printing or stereo lithography to build up the substrate 46d with the arcuate holes 78d.

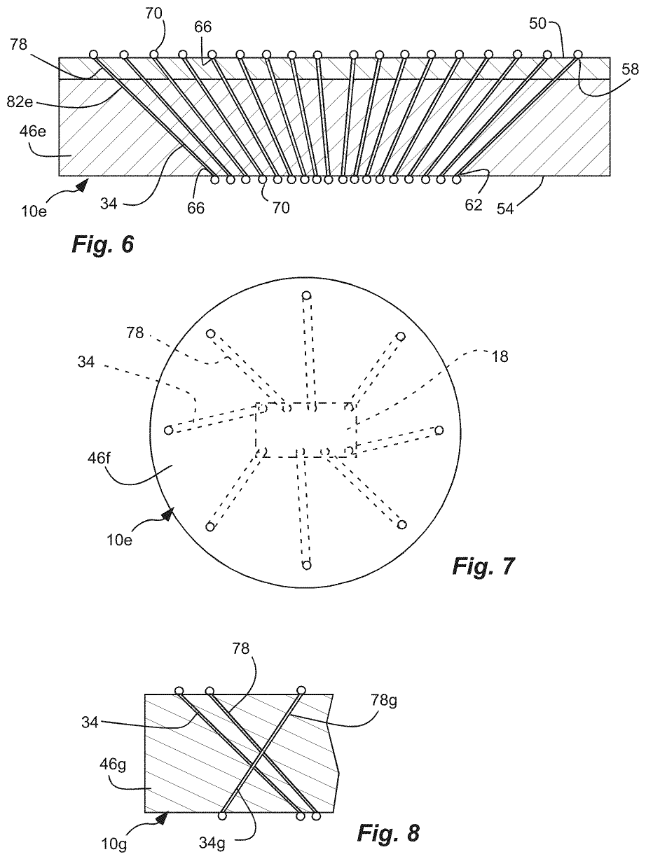

FIG. 6 is a schematic cross-sectional side view of a space transformer 10e in accordance with one example. The electrically conductive material can comprise wires 82e disposed through the holes 78. A mold layer 86 can be disposed on one of the sides of the substrate 46e. The mold layer 86 can circumscribe each wire 82e to hold the wire in place in the hole 78. Thus, the substrate 46e can comprise multiple portions or substrates joined together.

FIG. 7 is a schematic top view of a space transformer 10f in accordance with one example. The vias 34 and the holes 78 collectively can form a star burst pattern through the substrate 46f and the space transformer 10f.

FIG. 8 is a schematic partial cross-sectional side view of a space transformer 10g in accordance with one example. The vias 34 can comprise at least two vias 34 and 34g that extend in opposite directions, but without intersecting one another. Similarly, the holes 78 can comprise at least two holes 78 and 78g that extend in opposite directions, but without intersecting one another. The vias 34g and the holes 78g can intersect the other vias 34 and holes 78 with respect to a profile, or they cross one another in profile, but without intersecting.

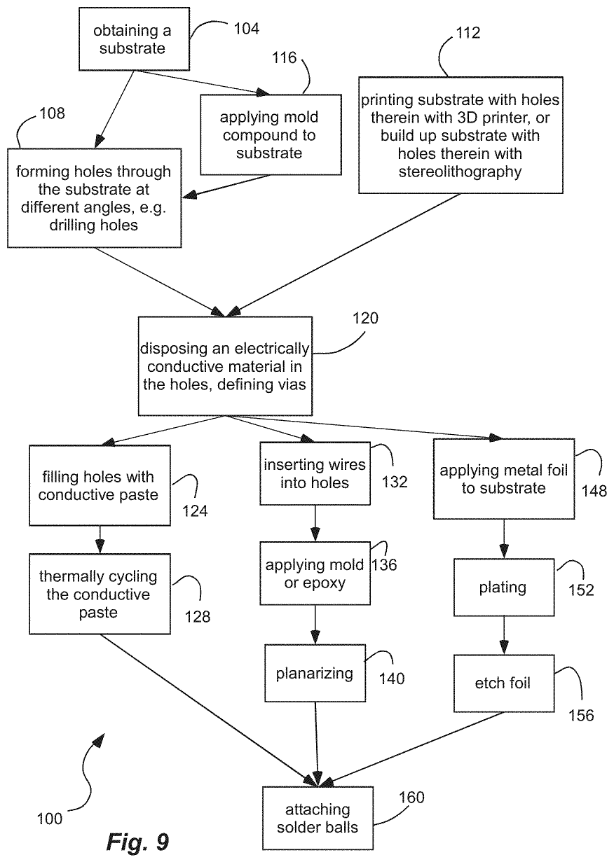

FIG. 9 illustrates a method 100 for making a space transformer, such as described with reference to FIGS. 2-8. The method 100 can comprise obtaining 104 a substrate. In one aspect, the substrate can have a size and shape (in x, y directions) to fit and/or mate with the PCB. In addition, the substrate has a thickness (in the z direction). In one aspect, the substrate can have a thickness between about 250-500 um (micrometers). In one aspect, the substrate can be formed of a material with a low coefficient of thermal expansion (CTE), and high modulus, and that is suitable for laser machining. For example, the material of the substrate can be or can comprise alumina, aluminum nitride, silicon nitride, etc. In one aspect, the substrate can be a homogeneous material. A homogeneous material can allow for thinner substrates. For example, the substrate can be a homogeneous material that is about 250-500 um thick. In another aspect, the material of the substrate can be or can comprise a heterogeneous material. A heterogeneous material can allow for a thicker substrate that can still be laser micro-machined. In one aspect, obtaining the substrate can comprise obtaining the substrate formed of a homogeneous material. In another aspect, obtaining the substrate can comprise obtaining the substrate formed of a heterogeneous material.

In addition, the method 100 can comprise forming holes 108 through the substrate oriented at different angles with respect to one another, as described above. In one aspect, forming holes can comprise forming linear holes, defining vias that are linear. In another aspect, forming holes can comprise forming holes that are non-linear, defining vias are non-linear. In another aspect, forming holes can comprise forming holes that are multi-angled with multiple angles in each hole at an obtuse angle with respect to one another. In another aspect, forming holes can comprise forming holes that are arcuate, defining vias are arcuate. In one aspect, forming the holes can comprise drilling the holes in the substrate. The holes can be drilled with a laser, a mechanical drill bit, or chemical etching.

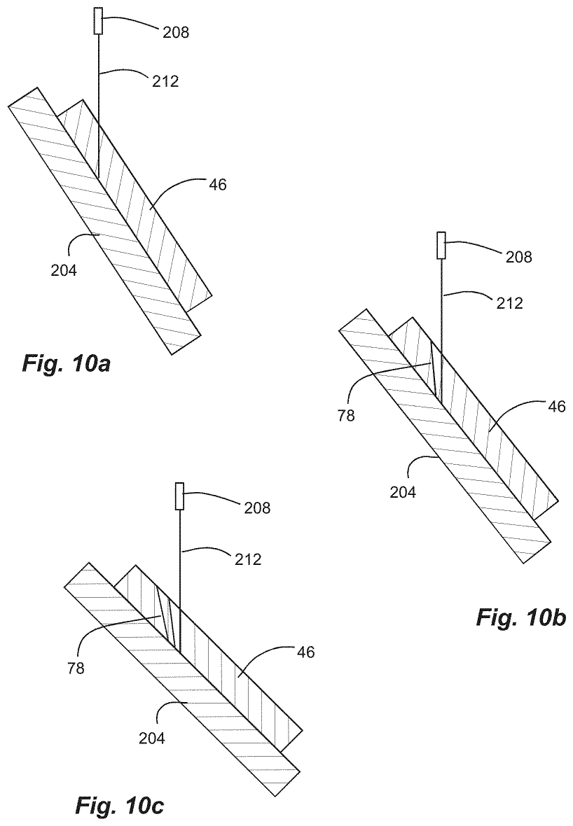

FIGS. 10a-10c illustrate a method for forming holes in the substrate, such as described with reference to FIGS. 2 and 9. The method can comprise affixing the substrate 46 to a platform 204. In one aspect, affixing the substrate 46 to a platform 204 can comprise affixing the substrate to a hexapod. The hexapod can be a 6-axis hexapod capable of up to 60 degree tilts. In another aspect, affixing the substrate 46 to a platform 204 can comprise affixing the substrate to a tilt stage stacked on top of a rotary stage. The hexapod or stacked stage can be located inside a laser machining system capable of drilling high accuracy and high precision holes.

The method can further comprise orienting the platform 204, and thus the substrate 46, with respect to a drill 208. The x, y coordinates of the fine pitch region can loaded into the laser machining system along with the desired loose pitch target. A translation code can determine the angle at which to drill each hole to achieve the desired pitch target. For each hole, tool software or the laser machining system can communicate with the hexapod and/or platform and provide the hexapod and/or platform with the coordinates in space and the angle that the hexapod and/or platform needs to be tilted.

The method can further comprise drilling the holes 78 with the drill 208. In one aspect, the drill 208 can comprise a laser drill. In one aspect, drilling the holes 78 can comprise drilling the holes with a laser beam 212. In another aspect, the drill 208 can comprise a mechanical drill bit, and drilling the holes 78 can comprise drilling the holes with the mechanical drill bit. In another aspect, drilling the holes can comprise drilling the holes 78 with a chemical etch, or chemically etching the holes through the substrate 46.

Referring again to FIG. 9 and the method 100 for making the space transformer, in another aspect, obtaining a substrate and forming holes through the substrate can comprise printing 112 the substrate with the holes therein with a 3D printer. In another aspect, obtaining the substrate and forming the holes can comprise building up, also indicated at 112, the substrate with the holes therein with stereolithography.

In one aspect, the method 100 can comprise applying 116 a mold compound to the substrate prior to forming the holes so that the holes are formed or drilled through the substrate and the mold compound.

The method 100 can further comprise disposing 120 an electrically conductive material in the holes, and extending through the substrate, defining vias oriented at different angles with respect to one another. In one aspect, the vias can form an array or grid on each side of the substrate. In another aspect, the vias can transform a pitch of ends of the vias on opposite sides of the substrate by less than three-quarters. In another aspect, the vias can transform a pitch of ends of the vias on opposite sides of the substrate by less than half. In another aspect, the vias can transform a pitch of ends of the vias on opposite sides of the substrate by less than a quarter.

In one aspect, disposing an electrically conductive material in the holes can comprise filling 124 the holes with a conductive paste, such as by using a squeegee to press the conductive paste into the holes. In one aspect, the conductive paste can be a solder paste. In addition, disposing an electrically conductive material in the holes can comprise thermal cycling 128 the substrate with the conductive past in the holes to solidify the conductive past and form the vias.

In another aspect, disposing an electrically conductive material in the holes can comprise inserting 132 conductive wires into each hole; applying 136 a mold or epoxy to hold the wires in place; and planarizing 140 the substrate to remove at least some of the mold or epoxy and to expose the wires.

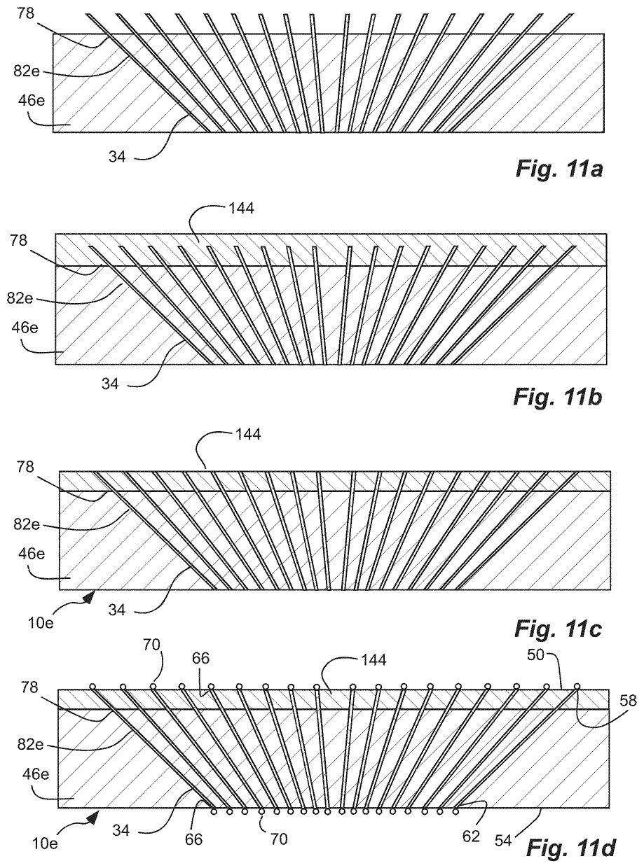

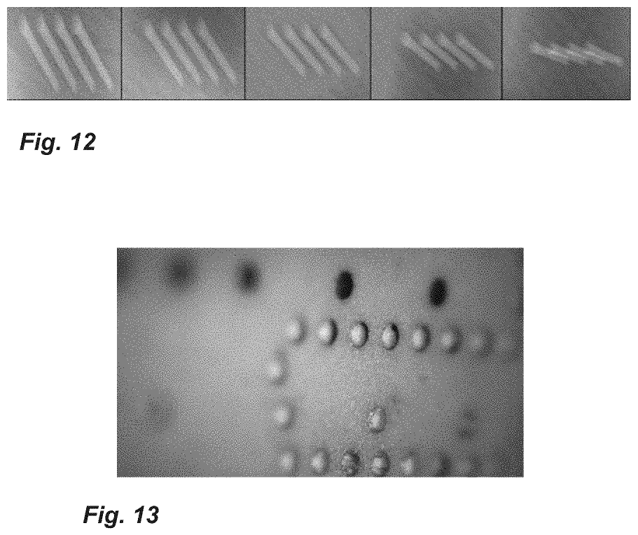

FIGS. 11a-11d illustrate a method for disposing an electrically conductive material in the holes, such as described with reference to FIGS. 6 and 9. As described above, disposing an electrically conductive material in the holes can comprise inserting (FIG. 11a) conductive wires 82e into each hole 78; applying (FIG. 11b) a mold or epoxy 144 to hold the wires 82e in place; and planarizing (FIG. 11c) the substrate 46e to remove at least some of the mold or epoxy 144 and to expose the wires 82e. (The method can also comprise disposing solder balls 70 on each end of the vias 34, as shown in FIG. 12c. The method can also comprise disposing probes 56 or wires 72 on each end of the vias 34 on the second side 54 of the substrate, as shown in FIG. 2.)

Referring again to FIG. 9 and the method 100 for making the space transformer, in another aspect, disposing an electrically conductive material in the holes can comprise applying 148 a metal foil to a side of the substrate, plating 152 the holes to form the vias, and removing 156 the foil from the substrate. In one aspect, removing the foil can comprise etching.

In another aspect, the disposing an electrically conductive material in the holes can comprise using chemical vapor deposition.

The method 100 can further comprise attaching 160 solder balls to ends of the vias. The method 100 can further comprise attaching probes or wires to ends of the vias.

FIG. 12 is a series of pictures of an x-ray cross-section of a ceramic substrate with holes drilled by a laser.

FIG. 13 is a picture of a substrate with holes filled with paste and cured to form vias.

Referring again to FIGS. 1a and 1b, a method for transforming a pad pitch Pp of pads 26 of a PCB 14 to a contact pitch Pc of contacts 30 of a die 18 is shown, where the method comprises: obtaining a space transformer 10 having vias 34 extending through the space transformer oriented at different angles with respect to one another; and operatively coupling the space transformer 10 to the PCB 14 with the vias 34 extending from the pads 26 of the PCB 14.

### EXAMPLES

The following examples pertain to further embodiments.

In one example there is provided a space transformer device configured for transforming a pitch of electrical contacts from a first distribution to a second distribution. The device comprises: a substrate with opposite first and second sides; and vias extending through the substrate between the first and second sides and oriented at different angles with respect to one another.

In one example of the space transformer device, the vias are linear.

In one example of the space transformer device, the vias are non-linear.

In one example of the space transformer device, the vias are multi-angled with multiple angles in each via at an obtuse angle with respect to one another.

In one example of the space transformer device, the vias are arcuate.

In one example of the space transformer device, the vias form an array or grid on each side of the substrate.

In one example of the space transformer device, the vias transform a pitch of the second distribution to less than three-quarters of a pitch of the first distribution.

In one example of the space transformer device, the vias transform a pitch of the second distribution to less than half of a pitch of the first distribution.

In one example of the space transformer device, the vias transform a pitch of the second distribution to less than a quarter of a pitch of the first distribution.

In one example of the space transformer device, further comprises: holes extending through the substrate between the first and second sides; an electrically conductive material disposed in the holes and extending between the first and second sides, and defining the vias through the substrate; and the holes having different angles with respect to one another.

In one example of the space transformer device, the electrically conductive material comprises wires disposed through the holes; and further comprises: a mold layer disposed on one of the sides of the substrate and circumscribing each wire.

In one example of the space transformer device, the vias collectively form a conical projection through the substrate.

In one example of the space transformer device, the vias collectively form a star burst through the substrate.

In one example of the space transformer device, at least two vias extend in opposite directions without intersecting one another.

In one example of the space transformer device, each end of the vias define an electrical contact.

In one example of the space transformer device, the electrical contacts on the second side of the substrate have a narrower pitch than the electrical contacts on the first side of the substrate.

In one example of the space transformer device, the device further comprises a bond pad at an end of each via.

In one example of the space transformer device, the device further comprises a solder ball at an end of each via.

In one example of the space transformer device, the substrate is formed of a homogeneous material.

In one example of the space transformer device, the substrate is formed of a heterogeneous material.

In one example there is provided a tester system for dies on a wafer, the system comprising: a PCB; and a space transformer as in any one of examples above operably coupled to the PCB.

In one example there is provided a tester system for a die. The tester system comprises: a PCB with pads having a pad pitch; and a space transformer operatively coupled to the PCB, and having vias extending from the pads of the PCB through the space transformer at different angles with respect to one another and configured to electrically connect to contacts on the die having a contact pitch different than the pad pitch.

In one example of the tester system, the vias are linear.

In one example of the tester system, the vias are non-linear.

In one example of the tester system, the vias are multi-angled with multiple angles in each via at an obtuse angle with respect to one another.

In one example of the tester system, the vias are arcuate.

In one example of the tester system, the vias form an array or grid on each side of the substrate.

In one example of the tester system, the vias transform the contact pitch to less than three-quarters of the pad pitch.

In one example of the tester system, the vias transform the contact pitch to less than half of the pad pitch.

In one example of the tester system, the vias transform the contact pitch to less than a quarter of the pad pitch.

In one example of the tester system, the space transformer further comprises: a substrate with a first side engaging the PCB and an opposite second side; and the vias extending through the substrate between the first and second sides.

In one example of the tester system, the tester system further comprises: holes extending through the substrate between the first and second sides; an electrically conductive material disposed in the holes and extending between the first and second sides, and defining the vias through the substrate; and the holes being oriented at different angles with respect to one another.

In one example of the tester system, the electrically conductive material comprises wires disposed through the holes; and further comprises: a mold layer disposed on one of the sides of the substrate and circumscribing each wire.

In one example of the tester system, the vias collectively form a conical projection through the substrate.

In one example of the tester system, the vias collectively form a star burst through the substrate.

In one example of the tester system, at least two vias extend in opposite directions without intersecting one another.

In one example of the tester system, each end of the vias define an electrical contact.

In one example of the tester system, the electrical contacts on the second side of the substrate have a narrower pitch than the electrical contacts on the first side of the substrate.

In one example of the tester system, the tester system further comprises a bond pad at an end of each via.

In one example of the tester system, the tester system further comprises a solder ball at an end of each via.

In one example of the tester system, the substrate is formed of a homogeneous material.

In one example of the tester system, the substrate is formed of a heterogeneous material.

In one example there is provided a method for making a space transformer, comprising: obtaining a substrate; forming holes through the substrate oriented at different angles with respect to one another; and disposing an electrically conductive material in the holes and extending through the substrate, defining vias oriented at different angles with respect to one another.

In one example of the method, forming holes comprises forming linear holes defining vias In one example of the method, forming holes comprises forming holes that are non-linear defining vias are non-linear.

In one example of the method, forming holes comprises forming holes that are multi-angled with multiple angles in each hole at an obtuse angle with respect to one another.

In one example of the method, forming holes comprises forming holes that are arcuate defining vias are arcuate.

In one example of the method, the vias form an array or grid on each side of the substrate.

In one example of the method, the vias transform a pitch of ends of the vias on opposite sides of the substrate by less than three-quarters.

In one example of the method, the vias transform a pitch of ends of the vias on opposite sides of the substrate by less than half.

In one example of the method, the vias transform a pitch of ends of the vias on opposite sides of the substrate by less than a quarter.

In one example of the method, obtaining the substrate comprises obtaining the substrate formed of a homogeneous material.

In one example of the method, obtaining the substrate comprises obtaining the substrate formed of a heterogeneous material.

In one example of the method, the method further comprises: affixing the substrate to a platform; and orienting the platform, and thus the substrate, with respect to a drill; and forming the holes comprises drilling the holes.

In one example of the method, affixing the substrate to a platform comprises affixing the substrate to a hexapod.

In one example of the method, affixing the substrate to a platform comprises affixing the substrate to a tilt stage stacked on top of a rotary stage.

In one example of the method, drilling the holes comprises drilling the holes with a laser beam.

In one example of the method, drilling the holes comprises drilling the holes with a mechanical drill bit.

In one example of the method, drilling the holes comprises drilling the holes with chemical etching.

In one example of the method, obtaining the substrate and forming the holes comprises printing the substrate with the holes therein with a 3D printer.

In one example of the method, obtaining the substrate and forming the holes comprises building up the substrate with the holes therein with stereolithography.

In one example of the method, disposing an electrically conductive material in the holes comprises using a squeegee to press a conductive paste into the holes, and thermal cycling the substrate with the conductive past in the holes to solidify the conductive past and form the vias.

In one example of the method, disposing an electrically conductive material in the holes comprises inserting conductive wires into each hole, applying a mold or epoxy to hold the wires in place, and planarizing the substrate to remove at least some of the mold or epoxy and to expose the wires.

In one example of the method, disposing an electrically conductive material in the holes comprises applying a metal foil to a side of the substrate, plating the holes to form the vias, and removing the foil from the substrate.

In one example of the method, disposing an electrically conductive material in the holes comprises using chemical vapor deposition.

In one example of the method, the method further comprises attaching solder balls to ends of the vias.

In one example there is provided a method for transforming a pad pitch of pads of a PCB to a contact pitch of contacts of a die. The method comprises: obtaining a space transformer having vias extending through the space transformer oriented at different angles with respect to one another; and operatively coupling the space transformer to the PCB with the multi-angled vias extending from the pads of the PCB.

In one example of the method, the vias are linear.

In one example of the method, the vias are non-linear.

In one example of the method, the vias are multi-angled with multiple angles in each via at an obtuse angle with respect to one another.

In one example of the method, the vias are arcuate.

In one example of the method, the vias form an array or grid on each side of the substrate.

In one example of the method, the vias transform the contact pitch to less than three-quarters of the pad pitch.

In one example of the method, the vias transform the contact pitch to less than half of the pad pitch.

In one example of the method, the vias transform the contact pitch to less than a quarter of the pad pitch.

In one example of the method, the space transformer further comprises: a substrate with a first side engaging the PCB and an opposite second side; and the multi-angled vias extending through the substrate between the first and second sides.

In one example of the method, the method further comprises: holes extending through the substrate between the first and second sides; an electrically conductive material disposed in the holes and extending between the first and second sides, and defining the vias through the substrate; and the holes being oriented different angles with respect to one another.

In one example of the method, the electrically conductive material comprises wires disposed through the holes; and the method further comprises a mold layer disposed on one of the sides of the substrate and circumscribing each wire.

In one example of the method, the vias collectively form a conical projection through the substrate.

In one example of the method, the vias collectively form a star burst through the substrate.

In one example of the method, at least two vias extend in opposite directions without intersecting one another.

In one example of the method, each end of the vias define an electrical contact.

In one example of the method, the electrical contacts on the second side of the substrate have a narrower pitch than the electrical contacts on the first side of the substrate.

In one example of the method, the method further comprises a bond pad at an end of each via.

In one example of the method, the method further comprises a solder ball at an end of each via.

In one example of the method, the substrate is formed of a homogeneous material.

In one example of the method, the substrate is formed of a heterogeneous material.

While the forgoing examples are illustrative of the specific embodiments in one or more particular applications, it will be apparent to those of ordinary skill in the art that numerous modifications in form, usage and details of implementation can be made without departing from the principles and concepts articulated herein.

1. A space transformer device configured for transforming a pitch of electrical contacts from a first distribution to a second distribution, the device comprising:
a substrate with opposite first and second sides; and
vias extending through the substrate between the first and second sides and oriented at different angles with respect to one another.

2. The space transformer device of claim 1, wherein the vias are linear.

3. The space transformer device of claim 1, wherein the vias are non-linear.

4. The space transformer device of claim 1, wherein the vias are multi-angled with multiple angles in each via at an obtuse angle with respect to one another.

5. The space transformer device of claim 1, wherein the vias are arcuate.

6. The space transformer device of claim 1, wherein the vias form an array or grid on each side of the substrate.

7. The space transformer device of claim 1, wherein the vias transform a pitch of the second distribution to less than three-quarters of a pitch of the first distribution.

8. The space transformer device of claim 1, wherein the vias transform a pitch of the second distribution to less than half of a pitch of the first distribution.

9. The space transformer device of claim 1, wherein the vias transform a pitch of the second distribution to less than a quarter of a pitch of the first distribution.

10. The space transformer device of claim 1, further comprising:
holes extending through the substrate between the first and second sides;
an electrically conductive material disposed in the holes and extending between the first and second sides, and defining the vias through the substrate; and
the holes having different angles with respect to one another.

11. The space transformer device of claim 10, wherein the electrically conductive material comprises wires disposed through the holes; and further comprising:
a mold layer disposed on one of the sides of the substrate and circumscribing each wire.

12. The space transformer device of claim 1, wherein the vias collectively form a conical projection through the substrate.

13. The space transformer device of claim 1, wherein the vias collectively form a star burst through the substrate.

14. The space transformer device of claim 1, wherein at least two vias extend in opposite directions without intersecting one another.

15. The space transformer device of claim 1, wherein each end of the vias define an electrical contact.

16. The space transformer device of claim 15, wherein the electrical contacts on the second side of the substrate have a narrower pitch than the electrical contacts on the first side of the substrate.

17. The space transformer device of claim 1, further comprising a bond pad at an end of each via.

18. The space transformer device of claim 1, further comprising a solder ball at an end of each via.

19. The space transformer device of claim 1, wherein the substrate is formed of a homogeneous material.

20. The space transformer device of claim 1, wherein the substrate is formed of a heterogeneous material.

21-42. (canceled)

43. A method for making a space transformer, comprising:
obtaining a substrate;
forming holes through the substrate oriented at different angles with respect to one another; and
disposing an electrically conductive material in the holes and extending through the substrate, defining vias oriented at different angles with respect to one another.

44-53. (canceled)

54. The method of claim 43, further comprising:
affixing the substrate to a platform; and
orienting the platform, and thus the substrate, with respect to a drill; and
wherein forming the holes comprises drilling the holes.

55-65. (canceled)

66. The method of claim 43, further comprising:
attaching solder balls to ends of the vias.

67-87. (canceled)
